(19) United States
(12) Patent Application Publication
(10) Pub. No.: US 2026/0251403 A1
(43) Pub. Date: Aug. 27, 2026

(54) HEAT DISSIPATION DEVICE WITH COMMUNICATION FUNCTION

(71) Applicant: HTC Corporation, Taoyuan City (TW)

(72) Inventors: Ta-Chun PU, Taoyuan City (TW); Chun-Yih WU, Taoyuan City (TW)

(73) Assignee: HTC Corporation, Taoyuan City (TW)

(21) Appl. No.: 19/092,038

(22) Filed: Mar. 27, 2025

(30) Foreign Application Priority Data
Feb. 25, 2025 (TW) 114106903

(51) Int. Cl. F28F 3/02; F28F 27/00

(52) U.S. Cl. CPC F28F 3/02; F28F 27/00

(57) ABSTRACT

A heat dissipation device with a communication function includes a conductive substrate, a plurality of general heat sink elements, and one or more specific heat sink elements. The conductive substrate has a feeding port. The general heat sink elements are coupled to the conductive substrate. The specific heat sink elements are coupled to the conductive substrate, and are disposed between the general heat sink elements. Each of the specific heat sink elements has a notch. A first antenna structure is formed by the conductive substrate and the specific heat sink elements.

### CROSS REFERENCE TO RELATED APPLICATIONS

This application claims priority of Taiwan Patent Application No. 114106903 filed on February 25, 2025, the entirety of which is incorporated by reference herein.

### BACKGROUND OF THE INVENTION

### Field of the Invention

The disclosure is generally related to a heat dissipation device, and more particularly, it is related to a heat dissipation device with a communication function.

### Description of the Related Art

With the advancements being made in mobile communication technology, mobile devices such as portable computers, mobile phones, multimedia players, and other hybrid functional portable electronic devices have become more common. To satisfy user demand, mobile devices can usually perform wireless communication functions. Some devices cover a large wireless communication area; these include mobile phones using 2G, 3G, and LTE (Long Term Evolution) systems and using frequency bands of 700MHz, 850MHz, 900MHz, 1800MHz, 1900MHz, 2100MHz, 2300MHz, 2500MHz, and 2700MHz. Some devices cover a small wireless communication area; these include mobile phones using Wi-Fi and Bluetooth systems and using frequency bands of 2.4GHz, 5.2GHz, and 5.8GHz.

Antennas are indispensable elements of mobile devices supporting wireless communication. However, since mobile devices and HMDs (Head Mounted Display) of VR (Virtual Reality), AR (Augmented Reality), MR (Mixed Reality), XR (Extended Reality), etc., have limited inner space, they cannot accommodate antenna elements with large sizes. Accordingly, there is a need to propose a novel solution for solving the problems of the prior art.

### BRIEF SUMMARY OF THE INVENTION

In an exemplary embodiment, the disclosure is directed to a heat dissipation device with a communication function. The heat dissipation device includes a conductive substrate, a plurality of general heat sink elements, and one or more specific heat sink elements. The conductive substrate has a feeding port. The general heat sink elements are coupled to the conductive substrate. The specific heat sink elements are coupled to the conductive substrate, and are disposed between the general heat sink elements. Each of the specific heat sink elements has a notch. A first antenna structure is formed by the conductive substrate and the specific heat sink elements.

In some embodiments, the general heat sink elements and the specific heat sink elements are substantially parallel to each other.

In some embodiments, the notches of the specific heat sink elements are substantially arranged in the same straight line.

In some embodiments, the first antenna structure covers a first frequency band, and the first frequency band is from 26GHz to 71GHz.

In some embodiments, each of the notches of the specific heat sink elements substantially has an isosceles triangular shape that is inverted, a regular triangular shape, a semicircular shape, an arc shape, or a square shape.

In some embodiments, the base length of the isosceles triangular shape is from 0.1 to 5 wavelengths of the first frequency band.

In some embodiments, the height of the isosceles triangular shape is from 0.1 to 5 wavelengths of the first frequency band.

In some embodiments, the distance between any adjacent two of the general heat sink elements and the specific heat sink elements is shorter than or equal to 0.25 wavelength of the first frequency band.

In some embodiments, the heat dissipation device further includes a feeding element coupled to a signal source. A second antenna structure is formed by the conductive substrate, the general heat sink elements, the specific heat sink elements, and the feeding element.

In some embodiments, the second antenna structure covers a second frequency band. The second frequency band is the same as or different from the first frequency band.

In some embodiments, the feeding port is adjacent to the specific heat sink elements.

In another exemplary embodiment, the invention is directed to a heat dissipation device with a communication function. The heat dissipation device includes a conductive substrate, a plurality of specific heat sink elements, and a waveguide. The heat sink elements are coupled to the conductive substrate. Each of the specific heat sink elements has a notch. The waveguide has a feeding port. A plurality of slots are formed on the waveguide. The notches of the specific heat sink elements are configured to accommodate the waveguide. The waveguide is used as a first antenna structure.

In some embodiments, the specific heat sink elements are substantially parallel to each other.

In some embodiments, each of the notches of the specific heat sink elements substantially has a rectangular shape or a square shape.

In some embodiments, the slots of the waveguide are substantially parallel to each other.

In some embodiments, the first antenna structure covers a first frequency band. The length of each of the slots of the waveguide is substantially equal to 0.5 wavelength of the first frequency band.

In some embodiments, the distance between any adjacent two of the slots of the waveguide is substantially equal to 0.5 wavelength of the first frequency band.

In some embodiments, the heat dissipation device further includes a feeding element coupled to a signal source. A second antenna structure is formed by the conductive substrate, the specific heat sink elements, and the feeding element.

In another exemplary embodiment, the invention is directed to a heat dissipation device with a communication function. The heat dissipation device includes a conductive substrate, a plurality of specific heat sink elements, a feeding element, and a pipeline element. The specific heat sink elements are coupled to the conductive substrate. Each of the specific heat sink elements has a notch. The feeding element is coupled to a signal source. An antenna structure is formed by the conductive substrate, the specific heat sink elements, and the feeding element. The notches of the specific heat sink elements are configured to accommodate the pipeline element.

In some embodiments, the pipeline element is made of a nonconductive material.

In some embodiments, cooling liquid or water is capable of flowing in the pipeline element.

In some embodiments, the pipeline element is made of a conductive material.

In some embodiments, the conductive substrate has a feeding port excited by a feeding waveguide. The feeding port is an opening on the conductive substrate. The feeding energy is transmitted from the feeding port into the pipeline element.

In some embodiments, the heat dissipation device further includes an extension structure coupled to an open end of the pipeline element.

In some embodiments, the extension structure is implemented with a horn antenna element.

In some embodiments, the heat dissipation device further includes a dielectric lens. The dielectric lens is connected to, embedded in, or arranged for covering an open end of the pipeline element.

In some embodiments, the dielectric lens is classified as a convex lens.

In some embodiments, the dielectric lens is classified as a concave lens.

### BRIEF DESCRIPTION OF DRAWINGS

The invention can be more fully understood by reading the subsequent detailed description and examples with references made to the accompanying drawings, wherein:

FIG. 1A is a perspective view of a heat dissipation device according to an embodiment of the invention;

FIG. 1B is a sectional view of a heat dissipation device according to an embodiment of the invention;

FIG. 2A is a perspective view of a heat dissipation device according to an embodiment of the invention;

FIG. 2B is a sectional view of a heat dissipation device according to an embodiment of the invention;

FIG. 2C is a sectional view of a heat dissipation device according to an embodiment of the invention;

FIG. 2D is a diagram of resonant paths of an antenna structure of a heat dissipation device according to an embodiment of the invention;

FIG. 3A is a diagram of a direct excitation mechanism of an antenna structure according to an embodiment of the invention;

FIG. 3B is a diagram of a coupling excitation mechanism of an antenna structure according to an embodiment of the invention;

FIG. 3C is a diagram of another direct excitation mechanism of an antenna structure according to an embodiment of the invention;

FIG. 4A is a perspective view of a heat dissipation device according to an embodiment of the invention;

FIG. 4B is a bottom view of a heat dissipation device according to an embodiment of the invention;

FIG. 4C is a sectional view of a heat dissipation device according to an embodiment of the invention;

FIG. 5 is a perspective view of a heat dissipation device according to an embodiment of the invention;

FIG. 6A is a perspective view of a heat dissipation device according to an embodiment of the invention;

FIG. 6B is a perspective view of a heat dissipation device according to an embodiment of the invention;

FIG. 6C is a partial view of a heat dissipation device according to an embodiment of the invention;

FIG. 6D is a partial view of a heat dissipation device according to an embodiment of the invention;

FIG. 6E is a partial view of a heat dissipation device according to an embodiment of the invention;

FIG. 6F is a partial view of a heat dissipation device according to an embodiment of the invention; and

FIG. 6G is a perspective view of a heat dissipation device according to an embodiment of the invention.

### DETAILED DESCRIPTION OF THE INVENTION

In order to illustrate the purposes, features and advantages of the invention, the embodiments and figures of the invention are shown in detail below.

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to…”. The term “substantially” means the value is within an acceptable error range. One skilled in the art can solve the technical problem within a predetermined error range and achieve the proposed technical performance. Also, the term “couple” is intended to mean either an indirect or direct electrical connection. Accordingly, if one device is coupled to another device, that connection may be through a direct electrical connection, or through an indirect electrical connection via other devices and connections.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

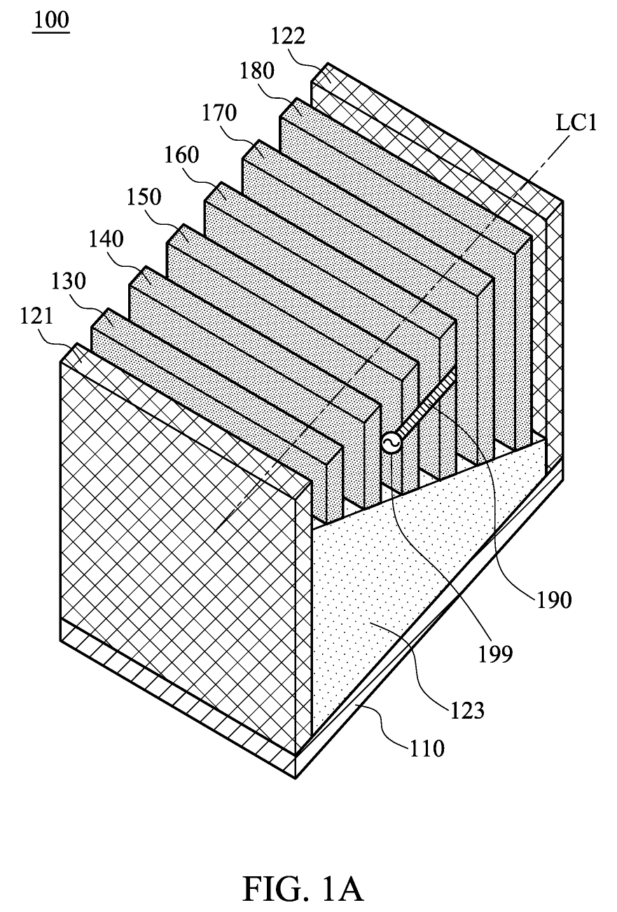

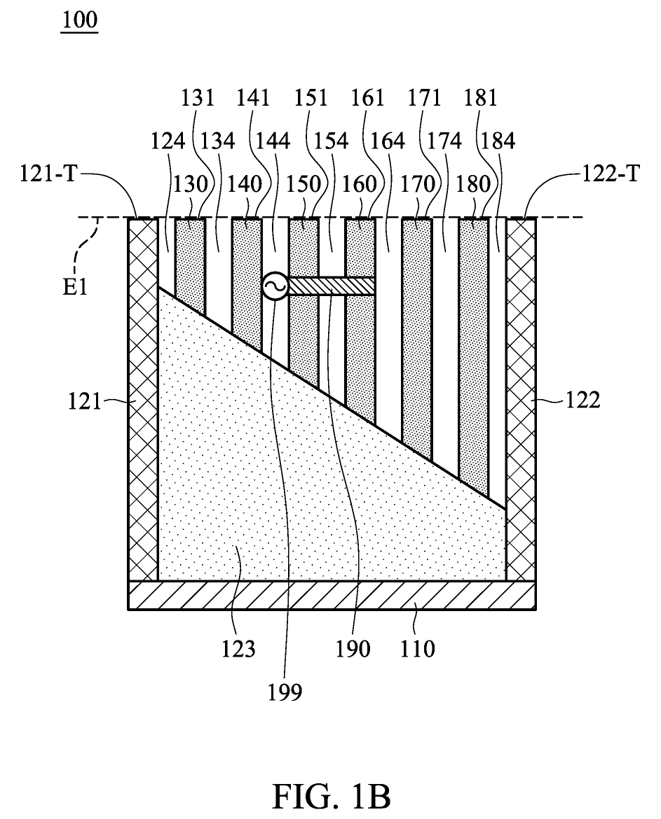

FIG. 1A is a perspective view of a heat dissipation device 100 according to an embodiment of the invention. FIG. 1B is a sectional view of the heat dissipation device 100 according to an embodiment of the invention (along a sectional line LC1). Please refer to FIG. 1A and FIG. 1B together. The heat dissipation device 100 may be applied to a mobile device, such as an HMD (Head Mounted Display), a smartphone, a tablet computer, or a notebook computer. In the embodiment of FIG. 1A and FIG. 1B, the heat dissipation device 100 at least includes a conductive substrate 110, a first conductive sidewall 121, a second conductive sidewall 122, a plurality of heat sink elements 130, 140, 150, 160, 170 and 180, and a feeding element 190. All of the above elements may be made of metal materials. It should be understood that the heat dissipation device 100 may further include other components, such as a connection element and/or a housing, although they are not displayed in FIG. 1A and FIG. 1B.

The number of heat sink elements 130, 140, 150, 160, 170 and 180 is not limited in the invention. In other embodiments, the heat dissipation device 100 may include more or fewer heat sink elements. The heat sink elements 130, 140, 150, 160, 170 and 180 have different lengths, and they are all positioned between the first conductive sidewall 121 and the second conductive sidewall 122. In some embodiments, the length of each of the heat sink elements 130, 140, 150, 160, 170 and 180 is shorter than or equal to the length of each of the first conductive sidewall 121 and the second conductive sidewall 122. The first conductive sidewall 121, the heat sink elements 130, 140, 150, 160, 170 and 180, and the second conductive sidewall 122 are respectively coupled to the conductive substrate 110. An antenna structure is formed by the feeding element 190, the conductive substrate 110, and the heat sink elements 130, 140, 150, 160, 170 and 180. In some embodiments, the aforementioned antenna structure further includes at least one of the first conductive sidewall 121 and the second conductive sidewall 122. That is, the heat dissipation device 100 can not only remove excess heat but also provide the function of wireless communication.

The first conductive sidewall 121, the heat sink elements 130, 140, 150, 160, 170 and 180, and the second conductive sidewall 122 may all be substantially perpendicular to the conductive substrate 110. Furthermore, the first conductive sidewall 121, the heat sink elements 130, 140, 150, 160, 170 and 180, and the second conductive sidewall 122 may be substantially parallel to each other. For example, any two adjacent elements from among the first conductive sidewall 121, the heat sink elements 130, 140, 150, 160, 170 and 180, and the second conductive sidewall 122 may substantially be the same distance apart, but they are not limited thereto.

The feeding element 190 is coupled to a signal source 199. For example, the signal source 199 may be an RF (Radio Frequency) module. The aforementioned antenna structure can be directly excited by the feeding element 190, or can be excited by the feeding element 190 using a coupling mechanism. In some embodiments, the feeding element 190 is integrated with the signal source 199, and they are implemented with a coaxial cable, a microstrip line, or an FPC (Flexible Printed Circuit Board).

In some embodiments, the heat dissipation device 100 further includes a conductive ramp element 123. The conductive ramp element 123 is disposed on the conductive substrate 110, and is configured to support and fix the heat sink elements 130, 140, 150, 160, 170 and 180 in such a way that terminals 131, 141, 151, 161, 171 and 181 of the heat sink elements 130, 140, 150, 160, 170 and 180 can be aligned with each other. For example, the terminals 131, 141, 151, 161, 171 and 181 of the heat sink elements 130, 140, 150, 160, 170 and 180 may be positioned on the same plane E1. In addition, the terminals 131, 141, 151, 161, 171 and 181, a first terminal 121-T of the first conductive sidewall 121, and a second terminal 122-T of the second conductive sidewall 122 may be aligned with each other, and they are all positioned on the same plane E1. Furthermore, the heat sink elements 130, 140, 150, 160, 170 and 180 may be further coupled through the conductive ramp element 123 to the conductive substrate 110. It should be understood that the conductive ramp element 123 is an optional component. In alternative embodiments, the conductive ramp element 123 is removable, so that the heat sink elements 130, 140, 150, 160, 170 and 180 may be arranged and directly coupled to the conductive substrate 110, respectively.

Since the heat sink elements 130, 140, 150, 160, 170 and 180 have different lengths, the first conductive sidewall 121, the heat sink elements 130, 140, 150, 160, 170 and 180, and the second conductive sidewall 122 can define a plurality of open slots 124, 123, 144, 154, 164, 174 and 184 with different lengths. For example, each of the open slots 124, 123, 144, 154, 164, 174 and 184 may have an open end and a closed end.

With respect to the antenna theory, since the open slots 124, 123, 144, 154, 164, 174 and 184 are excited to generate a plurality of resonant modes with different frequencies, the antenna structure of the heat dissipation device 100 is capable of covering a relatively large operation bandwidth. Specifically, the open slots 124 and 134 with short lengths correspond to relatively high-frequency bands, the open slots 144, 154 and 164 with median lengths correspond to relatively median-frequency bands, and the open slots 174 and 184 with long lengths correspond to relatively low-frequency bands.

In some embodiments, the antenna structure can cover a first frequency band and a second frequency band. The first frequency band may be from 2400MHz to 2500MHz. The second frequency band may be from 3100MHz to 7125MHz. Therefore, the antenna structure of the heat dissipation device 100 can support the wideband operations of conventional WLAN (Wireless Local Area Networks) and the next-generation 5G communication. With the design of the invention, the antenna structure for wireless communication is integrated with the heat dissipation device 100, and therefore the whole device size can be effectively reduced.

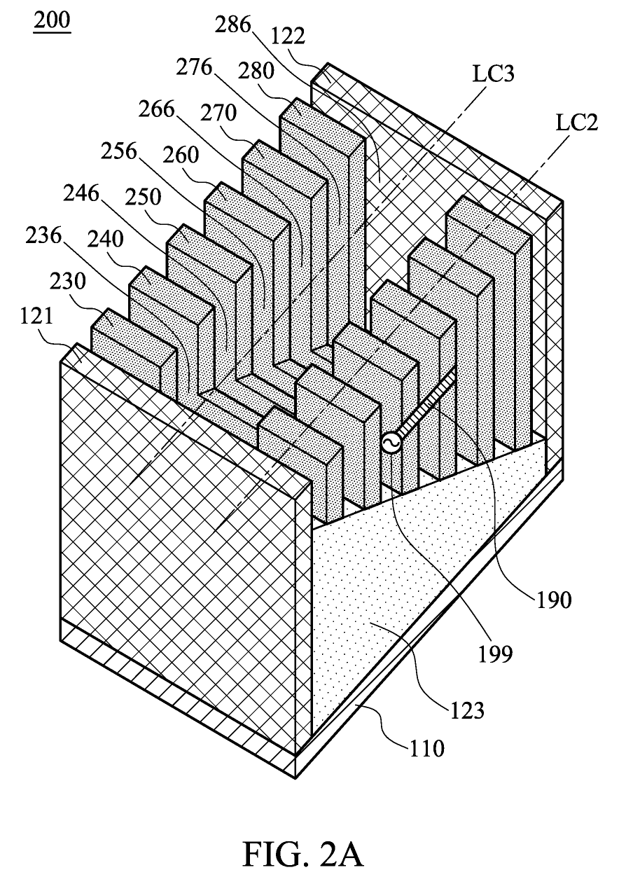

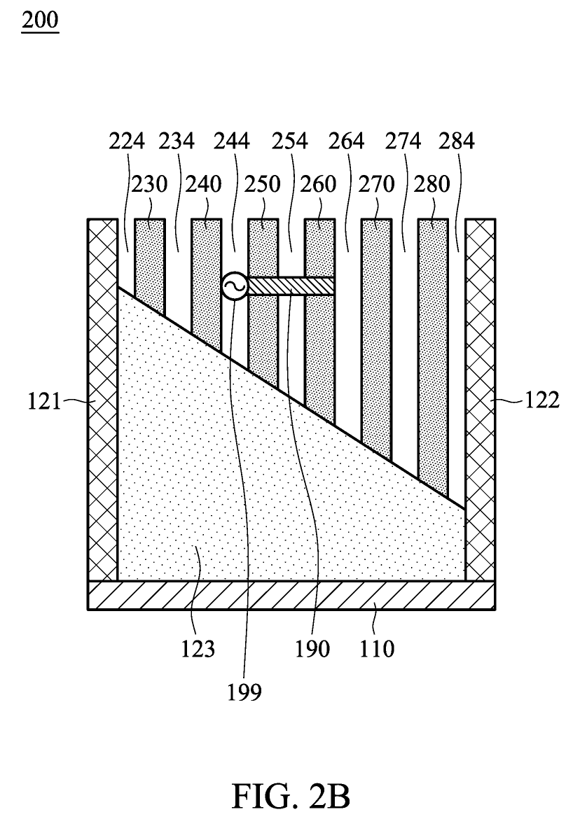

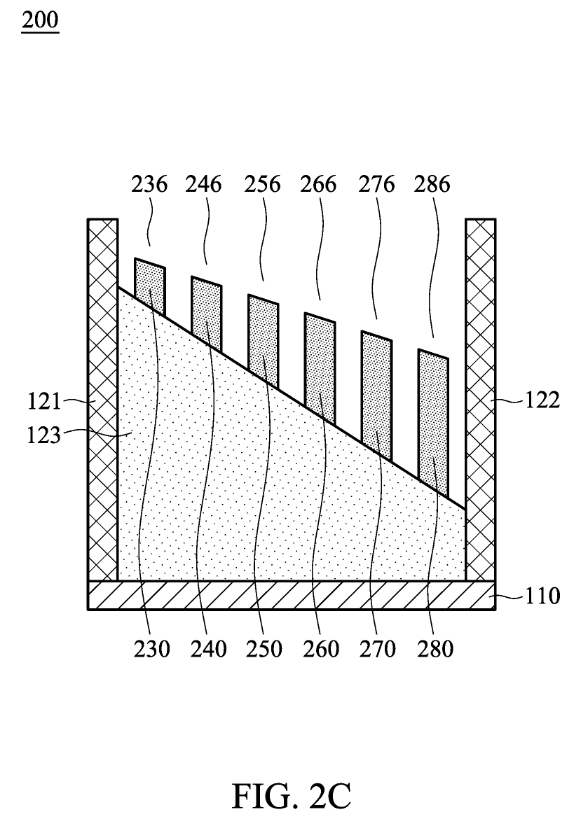

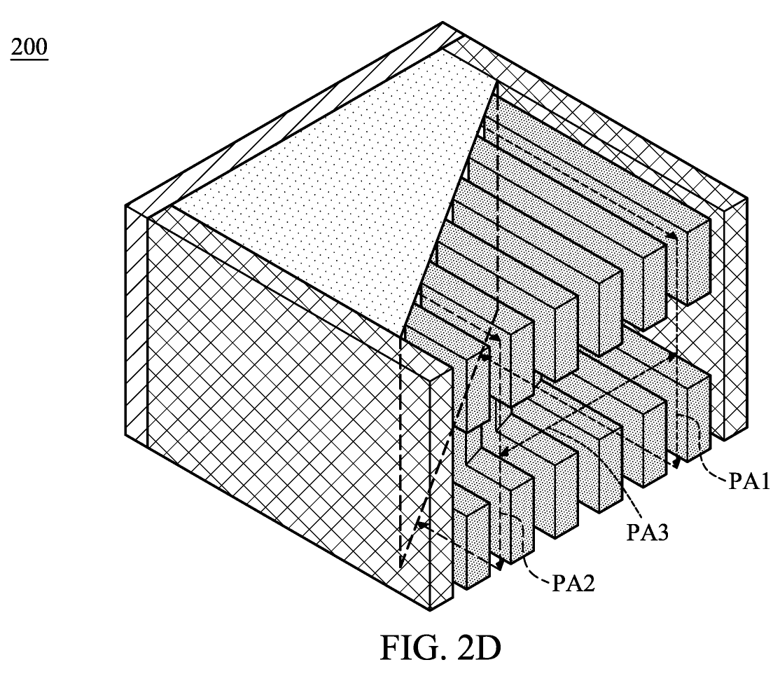

FIG. 2A is a perspective view of a heat dissipation device 200 according to an embodiment of the invention. FIG. 2B is a sectional view of the heat dissipation device 200 according to an embodiment of the invention (along a sectional line LC2). FIG. 2C is a sectional view of the heat dissipation device 200 according to an embodiment of the invention (along another sectional line LC3). Please refer to FIG. 2A, FIG. 2B and FIG. 2C together. FIG. 2A, FIG. 2B and FIG. 2C are similar to FIG. 1A and FIG. 1B. In the embodiment of FIG. 2A, FIG. 2B and FIG. 2C, a plurality of heat sink elements 230, 240, 250, 260, 270 and 280 of the heat dissipation device 200 have a plurality of notches 236, 246, 256, 266, 276 and 286, respectively. For example, each of the heat sink elements 230, 240, 250, 260, 270 and 280 may substantially have a U-shape, and each of the notches 236, 246, 256, 266, 276 and 286 may substantially have a rectangular shape. The notches 236, 246, 256, 266, 276 and 286 may have different lengths. Specifically, the notches 236 and 246 may have relatively short lengths, the notches 256 and 266 may have median lengths, and the notches 276 and 286 may have relatively long lengths. In addition, the notches 236, 246, 256, 266, 276 and 286 may be aligned with each other, and they may all be substantially arranged in a straight line (e.g., along the direction of the sectional line LC3). However, the invention is not limited thereto. In alternative embodiments, each of the notches 236, 246, 256, 266, 276 and 286 substantially has a semi-circular shape, a triangular shape, or a square shape.

Similarly, the heat sink elements 230, 240, 250, 260, 270 and 280 have different lengths, and they are all positioned between the first conductive sidewall 121 and the second conductive sidewall 122. The first conductive sidewall 121, the heat sink elements 230, 240, 250, 260, 270 and 280, and the second conductive sidewall 122 are respectively coupled to the conductive substrate 110 (e.g., through the conductive ramp element 123). An antenna structure is formed by the feeding element 190, the conductive substrate 110, and the heat sink elements 230, 240, 250, 260, 270 and 280. In some embodiments, the aforementioned antenna structure further includes at least one of the first conductive sidewall 121, the second conductive sidewall 122, and the conductive ramp element 123. Since the heat sink elements 230, 240, 250, 260, 270 and 280 have different lengths, the first conductive sidewall 121, the heat sink elements 230, 240, 250, 260, 270 and 280, and the second conductive sidewall 122 can define a plurality of open slots 224, 223, 244, 254, 264, 274 and 284 with different lengths. Each of the open slots 224, 223, 244, 254, 264, 274 and 284 may have an open end and a closed end.

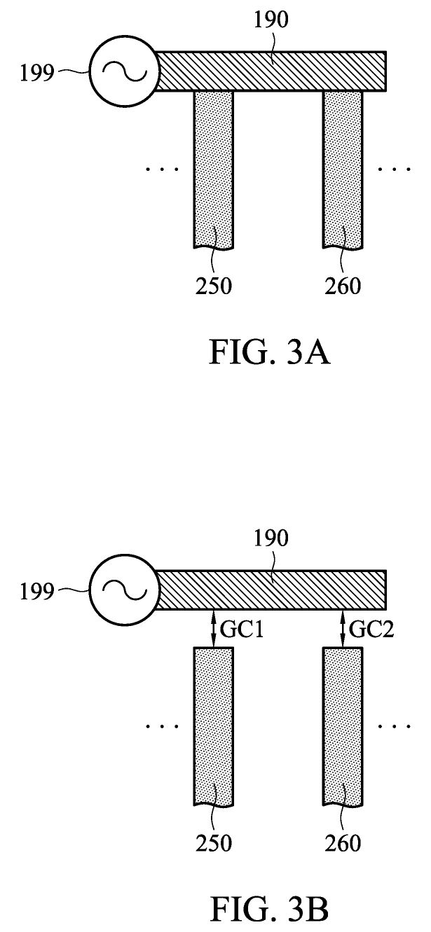

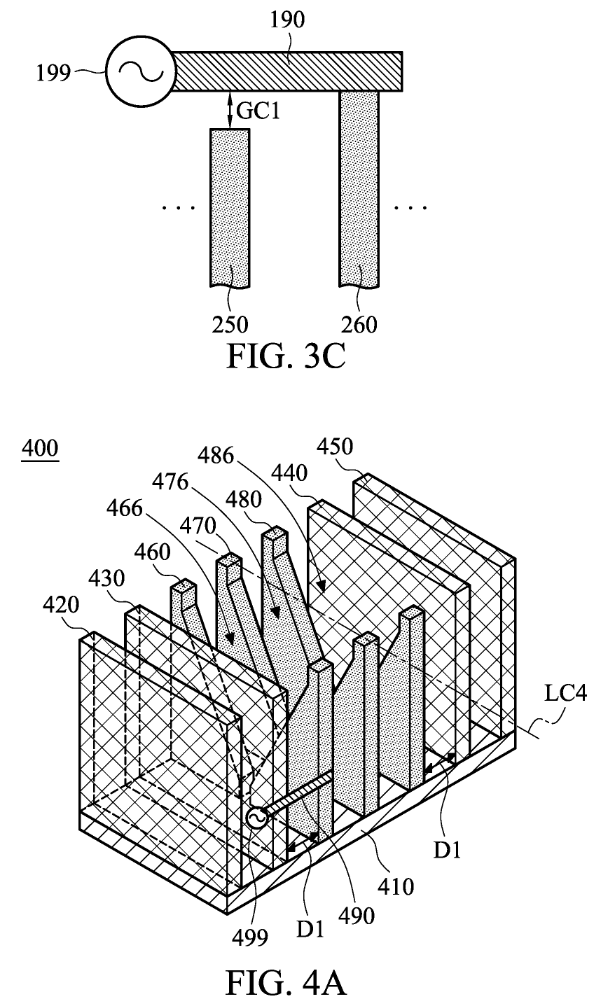

The antenna structure of the heat dissipation device 200 can be directly excited or excited using a coupling mechanism by the feeding element 190 and the signal source 199. FIG. 3A is a diagram of a direct excitation mechanism of the antenna structure according to an embodiment of the invention. In the embodiment of FIG. 3A, the feeding element 190 directly touches one or more of the heat sink elements 230, 240, 250, 260, 270 and 280 (e.g., the heat sink elements 250 and 260 at the middle position). FIG. 3B is a diagram of a coupling excitation mechanism of the antenna structure according to an embodiment of the invention. In the embodiment of FIG. 3B, the feeding element 190 is adjacent to but does not directly touch one or more of the heat sink elements 230, 240, 250, 260, 270 and 280 (e.g., the heat sink elements 250 and 260 at the middle position). FIG. 3C is a diagram of another direct excitation mechanism of the antenna structure according to an embodiment of the invention. In the embodiment of FIG. 3C, the feeding element 190 directly touches only one of the heat sink elements 230, 240, 250, 260, 270 and 280 (e.g., the heat sink elements 250 or 260 at the middle position). In alternative embodiments, the feeding element 190 is not limited to a monopole antenna element, and it is replaced with a dipole antenna element (not shown). It should be noted that the term “adjacent” or “close” over the disclosure means that the distance (spacing) between two corresponding elements is shorter than a predetermined distance (e.g., 5mm or shorter), but often it does not mean that the two corresponding elements are touching each other directly (i.e., the aforementioned distance/spacing therebetween is reduced to 0). For example, a first coupling gap GC1 may be formed between the feeding element 190 and the heat sink element 250, and a second coupling gap GC2 may be formed between the feeding element 190 and the heat sink element 260, but they are not limited thereto. The direct excitation mechanism and the coupling excitation mechanism as described above do not affect the radiation performance of the antenna structure.

It should be noted that the notches 236, 246, 256, 266, 276 and 286 arranged in the same straight line are considered as a coupling channel, which helps to improve the transmission of electromagnetic energy and increase the operation bandwidth of the antenna structure. Furthermore, the design of the notches 236, 246, 256, 266, 276 and 286 can also increase the effective resonant lengths of the heat sink elements 230, 240, 250, 260, 270 and 280, thereby further reducing the size of the antenna structure.

FIG. 2D is a diagram of resonant paths of the antenna structure of the heat dissipation device 200 according to an embodiment of the invention. As shown in FIG. 2D, the antenna structure of the heat dissipation device 200 has a low-frequency resonant path PA1, a high-frequency resonant path PA2, and a coupling resonant path PA3. The low-frequency resonant path PA1 mainly consists of relatively long heat sink elements, and it corresponds to the aforementioned first frequency band. The high-frequency resonant path PA2 mainly consists of relatively short heat sink elements, and it corresponds to the aforementioned second frequency band. The coupling resonant path PA3 is configured to fine-tune the impedance of both the first frequency band and the second frequency band as described above, so as to optimize the antenna radiation performance.

The following embodiments will introduce different configurations and other structures of the proposed heat dissipation device. It should be understood that these figures and descriptions are merely exemplary, rather than limitations of the invention.

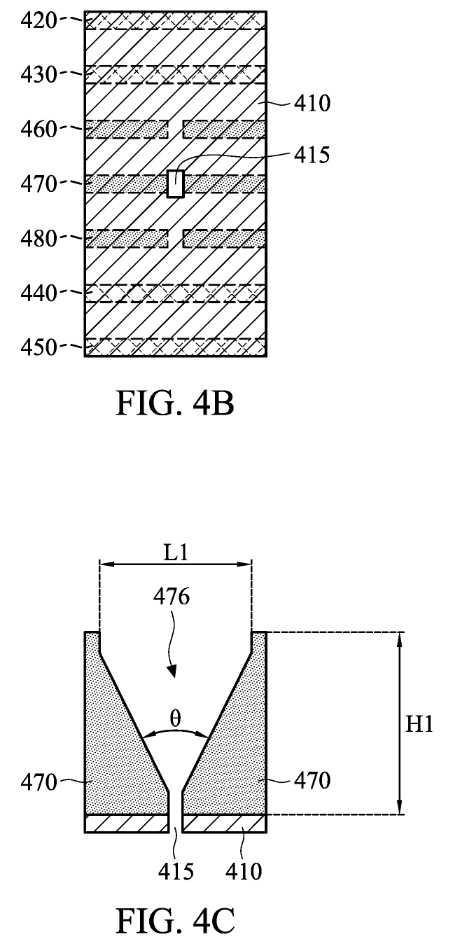

FIG. 4A is a perspective view of a heat dissipation device 400 according to an embodiment of the invention. FIG. 4B is a bottom view of the heat dissipation device 400 according to an embodiment of the invention. FIG. 4C is a sectional view of the heat dissipation device 400 according to an embodiment of the invention (along a sectional line LC4). Please refer to FIG. 4A, FIG. 4B and FIG. 4C together. In the embodiment of FIG. 4A, FIG. 4B and FIG. 4C, the heat dissipation device 400 includes a conductive substrate 410, a plurality of general heat sink elements 420, 430, 440 and 450, and one or more specific heat sink elements 460, 470 and 480. All of the above elements may be made of metal materials.

In comparison to the previous embodiments, the conductive substrate 410 further has a feeding point 415. For example, the feeding port 415 may be an opening on the conductive substrate 410, and it may be excited by a feeding waveguide (not shown). In some embodiments, the feeding port 415 is substantially positioned at the central point of the conductive substrate 410, and the feeding port 415 is also adjacent to the central specific heat sink element 470, but it is not limited thereto.

The number of general heat sink elements 420, 430, 440 and 450 and the number of specific heat sink elements 460, 470 and 480 are not limited in the invention. In fact, the heat dissipation device 400 may include more or less general heat sink elements or specific heat sink elements. In other embodiments, the heat dissipation device 400 merely includes a single specific heat sink element 470 and two general heat sink element 420 and 450. For example, the general heat sink elements 420, 430, 440 and 450 and the specific heat sink elements 460, 470 and 480 may have the same lengths. The general heat sink elements 420, 430, 440 and 450 are arranged and coupled to the conductive substrate 410. The specific heat sink elements 460, 470 and 480 are arranged and coupled to the conductive substrate 410. The specific heat sink elements 460, 470 and 480 are disposed between the general heat sink elements 420, 430, 440 and 450. Specifically, the specific heat sink elements 460, 470 and 480 have a plurality of notches 466, 476 and 486, respectively. For example, each of the notches 466, 476 and 486 may substantially have an isosceles triangular shape that is inverted. In addition, the notches 466, 476 and 486 may be aligned with each other, and they may be substantially arranged in the same straight line. In alternative embodiments, each of the notches 466, 476 and 486 substantially has a regular triangular shape, a semicircular shape, an arc shape, or a square shape, but it is not limited thereto.

The general heat sink elements 420, 430, 440 and 450 and the specific heat sink elements 460, 470 and 480 may all be substantially perpendicular to the conductive substrate 410. Furthermore, the general heat sink elements 420, 430, 440 and 450 and the specific heat sink elements 460, 470 and 480 may be substantially parallel to each other. For example, there may be an equal distance D1 between any adjacent two of the general heat sink elements 420, 430, 440 and 450 and the specific heat sink elements 460, 470 and 480. It should be understood that both the so-called “general heat sink element” and “specific heat sink element” are classified as heat sink elements, and their different names merely correspond to different shapes.

In some embodiments, a first antenna structure is formed by the conductive substrate 410 and the specific heat sink elements 460, 470 and 480, such that the heat dissipation device 400 supports the function of wireless communication. For example, the first antenna structure can cover a first frequency band, and the first frequency band may be from 26GHz to 71GHz (i.e., an mmWave (Millimeter Wave) frequency band), but it is not limited thereto.

With respect to the antenna theory, the radiation energy from the feeding port 415 of the conductive substrate 410 can be transmitted outwardly by using the specific heat sink elements 460, 470 and 480. It should be understood that the tapered design of the notches 466, 476 and 486 of the specific heat sink elements 460, 470 and 480 can help to reduce non-ideal reflections, thereby increasing the radiation efficiency of the first antenna structure.

In alternative embodiments, the heat dissipation device 400 further includes a feeding element 490, which is coupled to a signal source 499. A second antenna structure is formed by the conductive substrate 410, the general heat sink elements 420, 430, 440 and 450, the specific heat sink elements 460, 470 and 480, and the feeding element 490. The second antenna structure can be directly excited by the feeding element 490, or excited by the feeding element 490 using a coupling mechanism (referring to the embodiments of FIG. 3A, FIG. 3B and FIG. 3C). Furthermore, the second antenna structure can cover a second frequency band, and the second frequency band may be from 2400MHz to 7125MHz. It should be understood that the feeding element 490 is merely an optional component, which is omitted in other embodiments.

In some embodiments, the element sizes of the heat dissipation device 400 will be described as follows. Each of the notches 466, 476 and 486 of the specific heat sink elements 460, 470 and 480 may substantially have an isosceles triangular shape that is inverted. The base length L1 of the isosceles triangular shape may be from 0.1 to 5 wavelengths (0.1λ~5λ) of the first frequency band of the first antenna structure of the heat dissipation device 400. The height H1 of the isosceles triangular shape may be from 0.1 to 5 wavelengths (0.1λ~5λ) of the first frequency band of the first antenna structure of the heat dissipation device 400. In addition, the angle θ between the two legs of the isosceles triangular shape may be smaller than or equal to 60 degrees (e.g., 40 or 50 degrees). The distance D1 between any adjacent two of the general heat sink elements 420, 430, 440 and 450 and the specific heat sink elements 460, 470 and 480 may be shorter than or equal to 0.25 wavelength (λ/4) of the first frequency band of the first antenna structure of the heat dissipation device 400. The above ranges of element sizes and element parameters are calculated and obtained according to many experimental results, and they help to optimize the operational bandwidth and the impedance matching of the first antenna structure and the second antenna structure of the heat dissipation device 400.

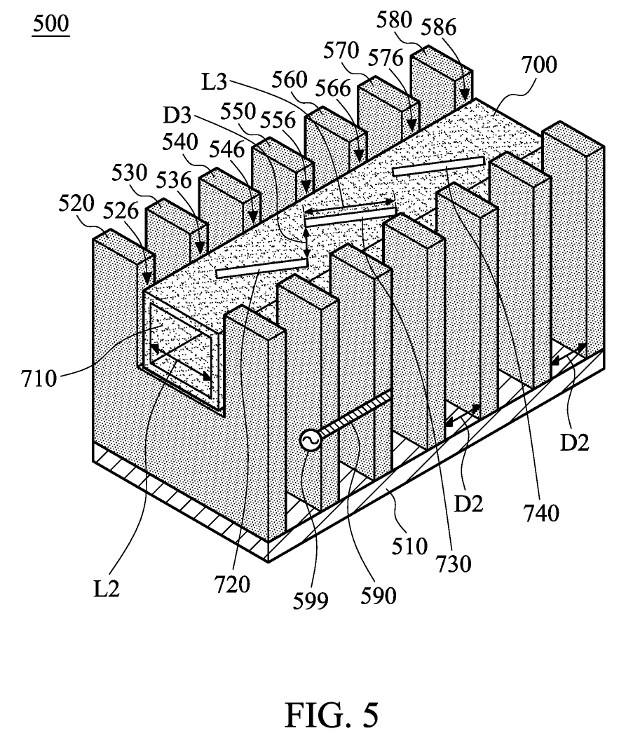

FIG. 5 is a perspective view of a heat dissipation device 500 according to an embodiment of the invention. In the embodiment of FIG. 5, the heat dissipation device 500 includes a conductive substrate 510, a plurality of specific heat sink elements 520, 530, 540, 550, 560, 570 and 580, and a waveguide 700. All of the above elements may be made of metal materials.

The number of specific heat sink elements 520, 530, 540, 550, 560, 570 and 580 is not limited in the invention. In other embodiments, the heat dissipation device 500 includes more or less specific heat sink elements. For example, the specific heat sink elements 520, 530, 540, 550, 560, 570 and 580 may have the same lengths. The specific heat sink elements 520, 530, 540, 550, 560, 570 and 580 are arranged and coupled to the conductive substrate 510. Specifically, the specific heat sink elements 520, 530, 540, 550, 560, 570 and 580 have a plurality of notches 526, 536, 546, 556, 566, 576 and 586, respectively. For example, each of the notches 526, 536, 546, 556, 566, 576 and 586 may substantially have a rectangular shape or a square shape. In addition, the notches 526, 536, 546, 556, 566, 576 and 586 may be aligned with each other, and they may be substantially arranged in the same straight line. In alternative embodiments, each of the notches 526, 536, 546, 556, 566, 576 and 586 substantially has a semicircular shape, an arc shape, a triangular shape, or a trapezoidal shape.

The specific heat sink elements 520, 530, 540, 550, 560, 570 and 580 may all be substantially perpendicular to the conductive substrate 510. Furthermore, the specific heat sink elements 520, 530, 540, 550, 560, 570 and 580 may substantially parallel to each other. For example, there may be an equal distance D2 between any adjacent two of the specific heat sink elements 520, 530, 540, 550, 560, 570 and 580.

The waveguide 700 has a feeding port 710. For example, the feeding port 710 may be a terminal opening of the waveguide 700, which may be excited by another signal source (not shown). A plurality of slots 720, 730 and 740 are formed on the waveguide 700. Similarly, the number of slots 720, 730 and 740 is adjustable according to different requirements. In some embodiments, each of slots 720, 730 and 740 of the waveguide 700 is a closed slot with a straight-line shape, an arc shape, or a meandering shape. The slots 720, 730 and 740 of the waveguide 700 may be substantially parallel to or aligned with each other, depending on the design requirement. In addition, the notches 526, 536, 546, 556, 566, 576 and 586 of the specific heat sink elements 520, 530, 540, 550, 560, 570 and 580 are configured to accommodate the waveguide 700. In some embodiments, the waveguide 700 is merely adjacent to the specific heat sink elements 520, 530, 540, 550, 560, 570 and 580, but it does not directly touch the specific heat sink elements 520, 530, 540, 550, 560, 570 and 580. In alternative embodiments, the shapes of the aforementioned notches match with the appearance shape of the waveguide 700, such that the waveguide 700 is fixed and disposed above the specific heat sink elements 520, 530, 540, 550, 560, 570 and 580.

In some embodiments, the waveguide 700 is used as a first antenna structure, such that the heat dissipation device 500 supports the function of wireless communication. For example, the first antenna structure can cover a first frequency band, and the first frequency band may be from 26GHz to 71GHz, but it is not limited thereto.

With respect to the antenna theory, the radiation energy from the waveguide 700 can be transmitted outwardly through the slots 720, 730 and 740. It should be noted that the waveguide 700 is well integrated with the specific heat sink elements 520, 530, 540, 550, 560, 570 and 580, so as to reduce the overall size of the heat dissipation device 500.

In alternative embodiments, the heat dissipation device 500 further includes a feeding element 590, which is coupled to a signal source 599. A second antenna structure is formed by the conductive substrate 510, the specific heat sink elements 520, 530, 540, 550, 560, 570 and 580, and the feeding element 590. The second antenna structure can be directly excited by the feeding element 590, or excited by the feeding element 590 using a coupling mechanism. Furthermore, the second antenna structure can cover a second frequency band.

In some embodiments, the element sizes of the heat dissipation device 500 will be described as follows. The length L2 of the feeding port 710 of the waveguide 700 may be substantially equal to 0.5 wavelength (λ/2) of the first frequency band of the first antenna structure of the heat dissipation device 500. The length L3 of each of the slots 720, 730 and 740 of the waveguide 700 may be substantially equal to 0.5 wavelength (λ/2) of the first frequency band of the first antenna structure of the heat dissipation device 500. The distance D2 between any adjacent two of the specific heat sink elements 520, 530, 540, 550, 560, 570 and 580 may be shorter than or equal to 0.25 wavelength (λ/4) of the second frequency band of the second antenna structure of the heat dissipation device 500. The distance between D3 any adjacent two of the slots 720, 730 and 740 of the waveguide 700 may be substantially equal to 0.5 wavelength (λ/2) of the first frequency band of the first antenna structure of the heat dissipation device 500. The above ranges of element sizes and element parameters are calculated and obtained according to many experimental results, and they help to optimize the operational bandwidth and the impedance matching of the first antenna structure and the second antenna structure of the heat dissipation device 500.

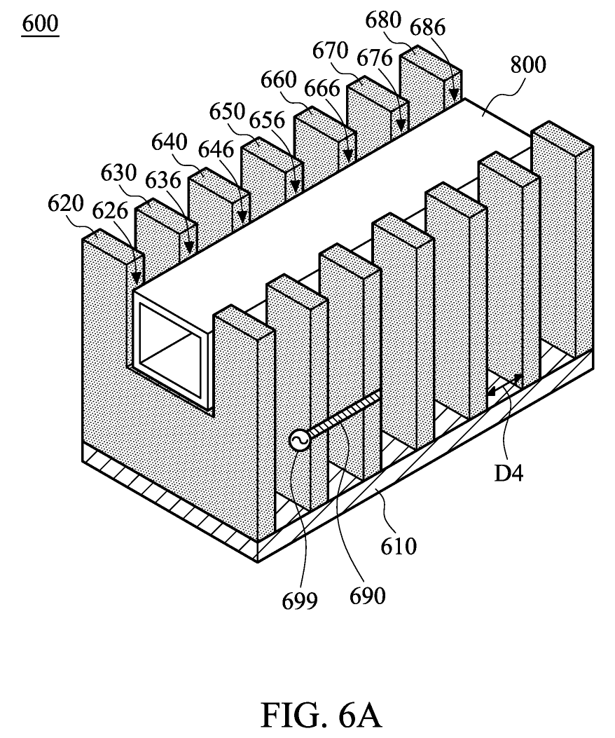

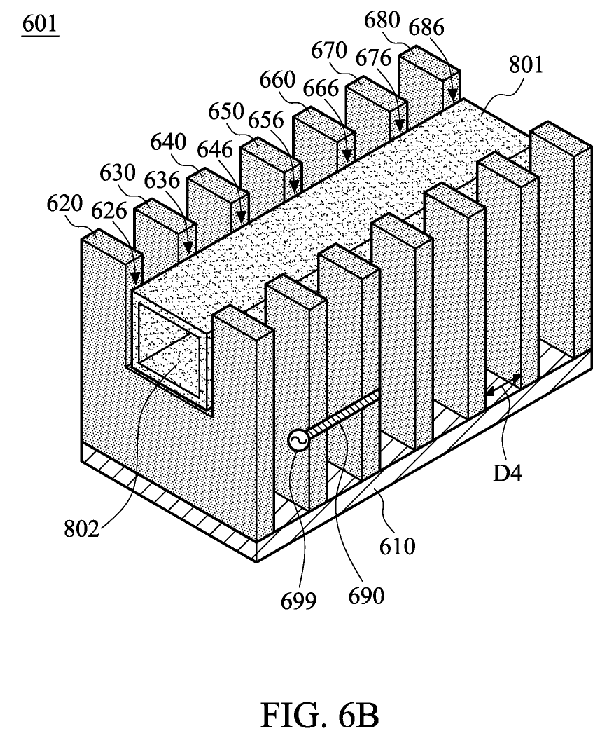

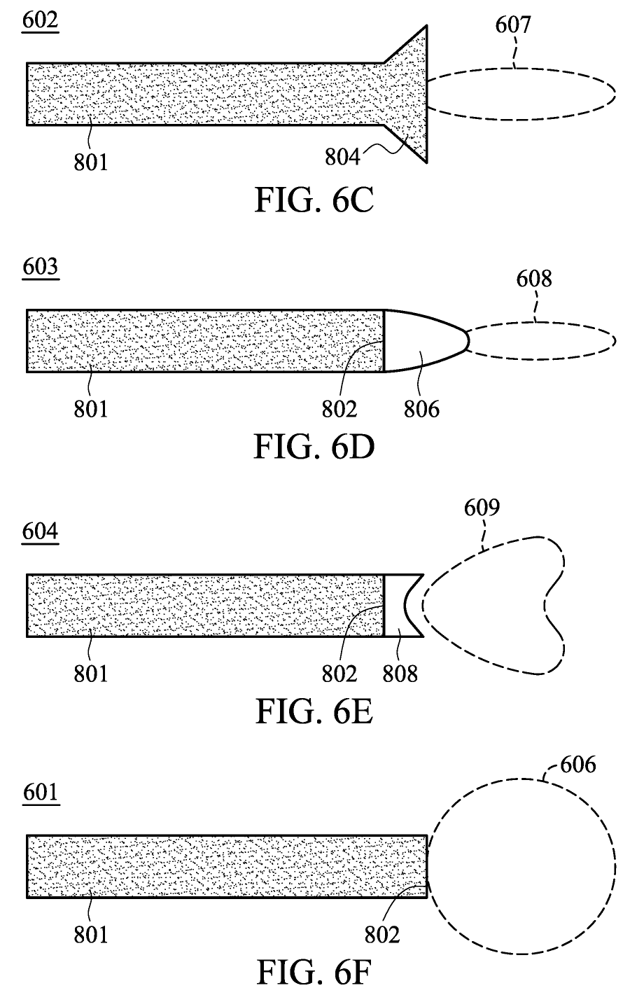

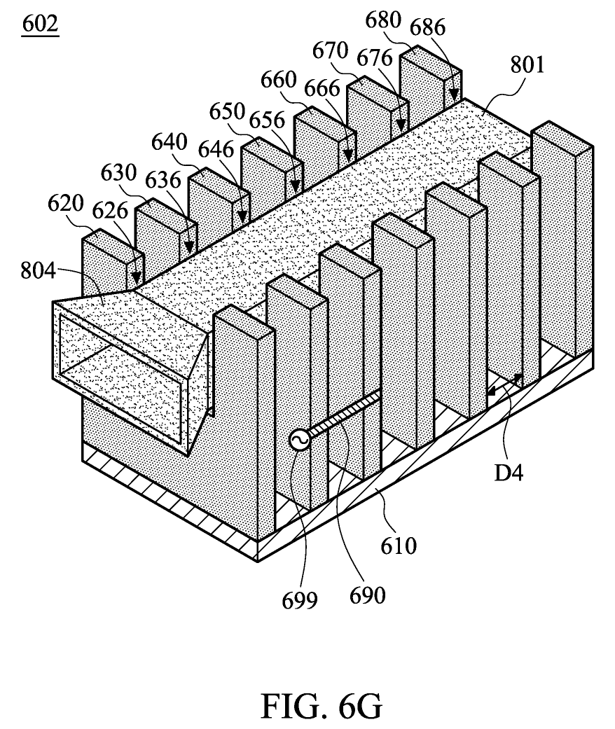

FIG. 6A is a perspective view of a heat dissipation device 600 according to an embodiment of the invention. In the embodiment of FIG. 6A, the heat dissipation device 600 includes a conductive substrate 610, a plurality of specific heat sink elements 620, 630, 640, 650, 660, 670 and 680, a feeding element 690, and a pipeline element 800. The conductive substrate 610, the specific heat sink elements 620, 630, 640, 650, 660, 670 and 680, and the feeding element 690 may all be made of metal materials. The pipeline element 800 may be made of a nonconductive material.

The number of specific heat sink elements 620, 630, 640, 650, 660, 670 and 680 is not limited in the invention. In other embodiments, the heat dissipation device 600 includes more or less specific heat sink elements. For example, the specific heat sink elements 620, 630, 640, 650, 660, 670 and 680 may have the same lengths. The specific heat sink elements 620, 630, 640, 650, 660, 670 and 680 are arranged and coupled to the conductive substrate 610. Specifically, the specific heat sink elements 620, 630, 640, 650, 660, 670 and 680 have a plurality of notches 626, 636, 646, 656, 666, 676 and 686, respectively. For example, each of the notches 626, 636, 646, 656, 666, 676 and 686 may substantially have a rectangular shape or a square shape. In addition, the notches 626, 636, 646, 656, 666, 676 and 686 may be aligned with each other, and they may be substantially arranged in the same straight line. In alternative embodiments, each of the notches 626, 636, 646, 656, 666, 676 and 686 substantially has a semicircular shape, an arc shape, a triangular shape, or a trapezoidal shape.

The specific heat sink elements 620, 630, 640, 650, 660, 670 and 680 may all be substantially perpendicular to the conductive substrate 610. Furthermore, the specific heat sink elements 620, 630, 640, 650, 660, 670 and 680 may be substantially parallel to each other. For example, there may be an equal distance D4 between any adjacent two of the specific heat sink elements 620, 630, 640, 650, 660, 670 and 680.

The feeding element 690 is coupled to a signal source 699. An antenna structure is formed by the conductive substrate 610, the specific heat sink elements 620, 630, 640, 650, 660, 670 and 680, and the feeding element 690. The antenna structure can be directly excited by the feeding element 690, or excited by the feeding element 690 using a coupling mechanism. Thus, the heat dissipation device 600 supports the function of wireless communication. For example, the antenna structure can cover a frequency band, and the frequency band may be from 2400MHz to 7125MHz, but it is not limited thereto.

The notches 626, 636, 646, 656, 666, 676 and 686 of the specific heat sink elements 620, 630, 640, 650, 660, 670 and 680 are configured to accommodate the pipeline element 800. For example, the pipeline element 800 may directly touch the specific heat sink elements 620, 630, 640, 650, 660, 670 and 680, but it is not limited thereto. It should be noted that since the pipeline element 800 has a hollow structure, cooling liquid or water (not shown) can flow inside the pipeline element 800. Thus, the function of heat dissipation can be increased. According to practical measurements, the heat dissipation device 600 not only enhances the communication quality but also improves its heat dissipation efficiency.

In some embodiments, the element sizes of the heat dissipation device 600 will be described as follows. The distance D4 between any adjacent two of the specific heat sink elements 620, 630, 640, 650, 660, 670 and 680 may be shorter than or equal to 0.25 wavelength (λ/4) of the frequency band of the antenna structure of the heat dissipation device 600. The above ranges of element sizes and element parameters are calculated and obtained according to many experimental results, and they help to optimize the operational bandwidth and the impedance matching of the antenna structure of the heat dissipation device 600.

FIG. 6B is a perspective view of a heat dissipation device 601 according to an embodiment of the invention. Basically, the structure of FIG. 6B is substantially similar to that of FIG. 6A. The heat dissipation device 601 includes a conductive substrate 610, a plurality of specific heat sink elements 620, 630, 640, 650, 660, 670 and 680, a feeding element 690, and a pipeline element 801. The conductive substrate 610, the specific heat sink elements 620, 630, 640, 650, 660, 670 and 680, and the feeding element 690 may all be made of metal materials. The pipeline element 801 with an open end 802 and a closed end (not shown) may be made of a conductive material (e.g., a metal waveguide). As shown in FIG. 4A and FIG. 4B and their work theory, the conductive substrate 610 further has a feeding port, which may be an opening on the conductive substrate 610 and may be excited by a feeding waveguide. Furthermore, the feeding energy may be transmitted from the feeding port into the pipeline element 801, delivered inside the pipeline element 801, and radiated at the open end 802 in the form of an antenna beam. The open end 802 of the pipeline element 801 is considered as a radiation aperture. The direction of the antenna beam can be changed by appropriately adjusting the shape, structure and material of the radiation aperture.

In the embodiment of FIG. 6B, the style of the open end 802 of the pipeline element 801 is the same as that of FIG. 6A. It should be noted that the open size of the aforementioned radiation aperture is adjustable according to a variety of requirements of the antenna design, so as to generate different radiation patterns. In addition, FIG. 6F is a partial view of the heat dissipation device 601 according to an embodiment of the invention. As shown in FIG. 6F, an antenna beam 606 of the heat dissipation device 601 is relatively wide.

FIG. 6C is a partial view of a heat dissipation device 602 according to an embodiment of the invention (e.g., the perspective view of the heat dissipation device 602 may be displayed in FIG. 6G). In the embodiment of FIG. 6C, the heat dissipation device 602 further includes an extension structure 804, which may be implemented with a horn antenna element. The extension structure 804 may extend outwardly to any specific heat sink element. For example, the extension structure 804 may be manufactured and integrated with the pipeline element 801. Alternatively, the extension structure 804 may be manufactured separately and then coupled to the open end 802 of the pipeline element 801. Compared with the embodiment of FIG. 6B, the extension structure 804 provides a larger radiation aperture for the pipeline element 801, thereby increasing its antenna gain and radiation efficiency. Furthermore, an antenna beam 607 of the heat dissipation device 602 is relatively narrow (in comparison to the embodiment of FIG. 6B), and it results in higher directivity.

FIG. 6D is a partial view of a heat dissipation device 603 according to an embodiment of the invention. In the embodiment of FIG. 6D, the heat dissipation device 603 further includes a dielectric lens 806. The dielectric lens 806 may extend outwardly to any specific heat sink element. For example, the dielectric lens 806 may be connected to, embedded in, or arranged for covering the open end 802 of the pipeline element 801. Since the dielectric lens 806 is classified as a convex lens, the antenna beam 608 of the heat dissipation device 603 can be more concentrated, thereby increasing its antenna gain and radiation efficiency.

FIG. 6E is a partial view of a heat dissipation device 604 according to an embodiment of the invention. In the embodiment of FIG. 6E, the heat dissipation device 604 further includes a dielectric lens 808. The dielectric lens 808 may extend outwardly to any specific heat sink element. For example, the dielectric lens 808 may be connected to, embedded in, or arranged for covering the open end 802 of the pipeline element 801. Since the dielectric lens 808 is classified as a concave lens, an antenna beam 609 of the heat dissipation device 604 can provide relatively weak center gain and relatively strong side gain.

The invention proposes a novel heat dissipation device for integrating heat sink elements with an antenna structure. Generally, the invention has at least the advantages of small size, wide bandwidth, reduced overall size, increased communication quality, changed radiation pattern, and/or improved heat dissipation efficiency, and therefore it is suitable for application in a variety of mobile communication devices with limited inner space.

Note that the above element sizes, element shapes, and frequency ranges are not limitations of the invention. An antenna designer can fine-tune these settings or values according to different requirements. It should be understood that the heat dissipation device of the invention is not limited to the configurations of FIGS. 1-6G. The invention may merely include any one or more features of any one or more embodiments of FIGS. 1-6G. In other words, not all of the features displayed in the figures should be implemented in the heat dissipation device of the invention.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A heat dissipation device with a communication function, comprising:
a conductive substrate, having a feeding port;
a plurality of general heat sink elements, coupled to the conductive substrate; and
one or more specific heat sink elements, coupled to the conductive substrate, and disposed between the general heat sink elements, wherein each of the specific heat sink elements has a notch;
wherein a first antenna structure is formed by the conductive substrate and the specific heat sink elements.

2. The heat dissipation device as claimed in claim 1, wherein the general heat sink elements and the specific heat sink elements are substantially parallel to each other.

3. The heat dissipation device as claimed in claim 1, wherein the notches of the specific heat sink elements are substantially arranged in a same straight line.

4. The heat dissipation device as claimed in claim 1, wherein the first antenna structure covers a first frequency band, and the first frequency band is from 26GHz to 71GHz.

5. The heat dissipation device as claimed in claim 4, wherein each of the notches of the specific heat sink elements substantially has an isosceles triangular shape that is inverted, a regular triangular shape, a semicircular shape, an arc shape, or a square shape.

6. The heat dissipation device as claimed in claim 5, wherein a base length of the isosceles triangular shape is from 0.1 to 5 wavelengths of the first frequency band.

7. The heat dissipation device as claimed in claim 5, wherein a height of the isosceles triangular shape is from 0.1 to 5 wavelengths of the first frequency band.

8. The heat dissipation device as claimed in claim 4, wherein a distance between any adjacent two of the general heat sink elements and the specific heat sink elements is shorter than or equal to 0.25 wavelength of the first frequency band.

9. The heat dissipation device as claimed in claim 4, further comprising:
a feeding element, coupled to a signal source, wherein a second antenna structure is formed by the conductive substrate, the general heat sink elements, the specific heat sink elements, and the feeding element.

10. The heat dissipation device as claimed in claim 9, wherein the second antenna structure covers a second frequency band, and the second frequency band is the same as or different from the first frequency band.

11. The heat dissipation device as claimed in claim 1, wherein the feeding port is adjacent to the specific heat sink elements.

12. A heat dissipation device with a communication function, comprising:
a conductive substrate;
a plurality of specific heat sink elements, coupled to the conductive substrate, wherein each of the specific heat sink elements has a notch; and
a waveguide, having a feeding port, wherein a plurality of slots are formed on the waveguide, and the notches of the specific heat sink elements are configured to accommodate the waveguide;
wherein the waveguide is used as a first antenna structure.

13. The heat dissipation device as claimed in claim 12, wherein the specific heat sink elements are substantially parallel to each other.

14. The heat dissipation device as claimed in claim 12, wherein each of the notches of the specific heat sink elements substantially has a rectangular shape or a square shape.

15. The heat dissipation device as claimed in claim 12, wherein the slots of the waveguide are substantially parallel to each other.

16. The heat dissipation device as claimed in claim 12, wherein the first antenna structure covers a first frequency band, and a length of each of the slots of the waveguide is substantially equal to 0.5 wavelength of the first frequency band.

17. The heat dissipation device as claimed in claim 16, wherein a distance between any adjacent two of the slots of the waveguide is substantially equal to 0.5 wavelength of the first frequency band.

18. The heat dissipation device as claimed in claim 12, further comprising:
a feeding element, coupled to a signal source, wherein a second antenna structure is formed by the conductive substrate, the specific heat sink elements, and the feeding element.

19. A heat dissipation device with a communication function, comprising:
a conductive substrate;
a plurality of specific heat sink elements, coupled to the conductive substrate, wherein each of the specific heat sink elements has a notch;
a feeding element, coupled to a signal source, wherein an antenna structure is formed by the conductive substrate, the specific heat sink elements, and the feeding element; and
a pipeline element, wherein the notches of the specific heat sink elements are configured to accommodate the pipeline element.

20. The heat dissipation device as claimed in claim 19, wherein the pipeline element is made of a nonconductive material.

21. The heat dissipation device as claimed in claim 20, wherein cooling liquid or water is capable of flowing in the pipeline element.

22. The heat dissipation device as claimed in claim 19, wherein the pipeline element is made of a conductive material.

23. The heat dissipation device as claimed in claim 22, wherein the conductive substrate has a feeding port excited by a feeding waveguide, the feeding port is an opening on the conductive substrate, and feeding energy is transmitted from the feeding port into the pipeline element.

24. The heat dissipation device as claimed in claim 22, further comprising:
an extension structure, coupled to an open end of the pipeline element.

25. The heat dissipation device as claimed in claim 24, wherein the extension structure is implemented with a horn antenna element.

26. The heat dissipation device as claimed in claim 22, further comprising:
a dielectric lens, wherein the dielectric lens is connected to, embedded in, or arranged for covering an open end of the pipeline element.

27. The heat dissipation device as claimed in claim 26, wherein the dielectric lens is classified as a convex lens.

28. The heat dissipation device as claimed in claim 26, wherein the dielectric lens is classified as a concave lens.
